(19) United States
(12) Patent Application Publication
(10) Pub. No.: US 2025/0273445 A1
(43) Pub. Date: Aug. 28, 2025

(54) SUBSTRATE PROCESSING APPARATUS

(71) Applicant: SEMES CO., LTD., Cheonan-si (KR)

(72) Inventors: Young Choon LIM, Cheonan-si (KR); Hyun Min LIM, Cheonan-si (KR); Seok Woo CHOI, Cheonan-si (KR); Tae Hun KIM, Cheonan-si (KR)

(73) Assignee: SEMES CO., LTD., Cheonan-si (KR)

(21) Appl. No.: 19/049,784

(22) Filed: Feb. 10, 2025

(30) Foreign Application Priority Data
Feb. 23, 2024 (KR) 10-2024-0026821

(51) Int. Cl. H01J 37/32

(52) U.S. Cl. CPC H01J 37/32743; H01J 37/32449; H01J 2237/204; H01J 2237/334

(57) ABSTRACT

Proposed is a substrate processing apparatus. The substrate processing apparatus includes a process chamber having an inner portion provided with a processing space for performing substrate processing, a transfer chamber including a transfer robot for transferring a substrate to the process chamber and being connected to the process chamber by a connection part, a first gas supply unit configured to supply a first gas to the inner portion of the process chamber, a second gas supply unit configured to supply a second gas to a substrate entrance passage that is a space inside the connection part, and a controller configured to control the first and second gas supply units. According to the substrate processing apparatus of the present disclosure, there is an effect that a problem of gas flow disturbance within a process chamber caused by a substrate entrance is capable of being solved.

### CROSS REFERENCE TO RELATED APPLICATION

The present application claims priority to Korean Patent Application No. 10-2024-0026821, filed Feb. 23, 2024, the entire contents of which are herein incorporated by reference herein for all purposes.

### BACKGROUND OF THE INVENTION

### Field of the Invention

The present disclosure relates to a substrate processing apparatus for processing a substrate.

### Description of the Related Art

A substrate processing device for performing a predetermined process on a substrate such as a semiconductor wafer disposed in a process chamber is generally used for manufacturing a semiconductor device. The predetermined process may include a deposition process for forming a predetermined film on a surface of a substrate, an etching process for forming a predetermined pattern on the film formed on the substrate, and so on.

In a substrate processing process, it is very important to perform a uniform processing over the entire surface area of a substrate. To this end, technology for adjusting the substrate processing temperature for each substrate region, technology for adjusting the plasma density such that the plasma density at the center region of a substrate and the plasma density at the outer peripheral region of the substrate are uniform, and so on have been proposed.

Meanwhile, an entrance for transferring a substrate into a process chamber and for transferring a processed substrate from the process chamber is formed in a portion of the side wall of the process chamber. The entrance is connected to a transfer chamber, and is configured such that a substrate is capable of being transferred between the transfer chamber and the process chamber. However, since such an entrance is formed only in a specific direction toward a substrate, the entrance may affect a substrate processing process. For example, a heat loss may occur in a direction toward the entrance from a substrate in which the temperature of the substrate is adjusted to the processing temperature, or gas flow disturbance may occur at the position of the entrance. As a result, the process uniformity of a substrate may be deteriorated.

In order to solve this problem, technology of blocking an entrance with a shutter after a substrate is transferred, technology of forming a dummy opening in addition to the entrance for the actual substrate entry and exit, and so on have been proposed. However, since it is difficult to completely block the gas flow by the shutter and there is a limitation in terms of effectiveness in forming a dummy opening, a more advanced technology for solving the process uniformity deterioration problem caused by an entrance is required.

### Document of Related Art

(Patent Document 1) KR 10-2189151 B1

(Patent Document 2) KR 10-2262026 B1

### SUMMARY OF THE INVENTION

Accordingly, the present disclosure has been made keeping in mind the above problems occurring in the related art, and an objective of the present disclosure is to provide a substrate processing apparatus capable of solving a problem of gas flow disturbance on a substrate, the gas flow disturbance caused by a substrate entrance formed in an inner wall of a process chamber.

In addition, another objective of the present disclosure is to provide a substrate processing apparatus capable of finely adjusting a process condition for a region of a substrate toward a substrate entrance.

In order to achieve the objectives as described above, according to an aspect of the present disclosure, there is provide a substrate processing apparatus including: a process chamber providing a processing space for performing substrate processing; a transfer chamber including a transfer robot for transferring a substrate to the process chamber, the transfer chamber being connected to the process chamber by a connection part; a first gas supply unit configured to supply a first gas to the processing space; a second gas supply unit configured to supply a second gas to a substrate entrance passage that is a space inside the connection part; and a controller configured to control the first gas supply unit and the second gas supply unit.

A first opening for allowing the substrate to enter and exit therethrough may be formed on a side wall of the process chamber, a second opening for allowing the substrate to enter and exit therethrough may be formed on a side wall of the transfer chamber, and the first opening and the second opening may be in communication with each other by the substrate entrance passage.

The substrate processing apparatus according to an aspect of the present disclosure may further include: an opening and closing door configured to be moved between an opening position for opening the second opening and a closing position for closing the second opening; and a shutter configured to be moved between an opening position for opening the first opening and a blocking position for blocking the first opening.

According to an aspect of the present disclosure, the first gas supply unit may include a first gas supply source and a first gas flow rate controller, and the first gas supply unit may be configured to supply the first gas to the processing space through a first gas inlet that is provided in the process chamber. Furthermore, the second gas supply unit may include a second gas supply source and a second gas flow rate controller, and the second gas supply unit may be configured to supply the second gas to the substrate entrance passage through a second gas inlet formed in a connection housing of the connection part. Furthermore, the controller may be configured to control the first gas flow rate controller and the second gas flow rate controller so that periods during which the first gas and the second gas are supplied overlap at least partially.

According to an aspect of the present disclosure, a shutter lift opening may be formed in the connection housing such that the shutter is capable of being moved to the substrate entrance passage.

According to an aspect of the present disclosure, the controller may be configured to control the second gas supply unit such that the second gas is supplied to the substrate entrance passage when the opening and closing door is positioned in the closing position and the shutter is positioned in the blocking position.

According to an aspect of the present disclosure, the first gas supply source and the second gas supply source may be the same common gas supply source.

According to another aspect of the present disclosure, there is provided a substrate processing apparatus including: a process chamber providing a processing space for performing substrate processing, the process chamber having a side wall provided with a first opening for allowing a substrate to enter and exit therethrough; a transfer chamber including a transfer robot for transferring the substrate to the process chamber, the transfer chamber having a side wall provided with a second opening for allowing the substrate to enter and exit therethrough; a connection part connecting the first opening of the process chamber and the second opening of the transfer chamber to each other, the connection part having an inner portion provided with a substrate entrance passage; a first gas supply unit configured to supply a first gas to the processing space; a second gas supply unit configured to supply a second gas to the substrate entrance passage; and a controller, wherein the controller is configured to control the first gas supply unit such that the first gas is supplied to the processing space after the substrate is transferred to the processing space, and the controller is configured to control the second gas supply unit such that the second gas is supplied to the substrate entrance passage while the first gas is supplied to the processing space.

The substrate processing apparatus according to another aspect of the present disclosure may further include: an opening and closing door configured to be operated by an opening and closing door driving unit such that the opening and closing door is moved between an opening position for opening the second opening and a closing position for closing the second opening; and a shutter configured to be operated by a power source such that the shutter is moved between an opening position for opening the first opening and a blocking position for blocking the first opening, wherein the controller may be configured to control the opening and closing door driving unit, the power source, and the second gas supply unit such that the second gas is supplied to the substrate entrance passage in a state in which the opening and closing door is positioned in the closing position and the shutter is positioned in the blocking position.

According to another aspect of the present disclosure, the first gas may include a process gas and an inert gas, and the second gas may include at least an inert gas.

According to another aspect of the present disclosure, both the first gas and the second gas may include a process gas and an inert gas. Furthermore, the controller may be configured to control the first gas supply unit and the second gas supply unit such that the first gas and the second gas are supplied at flow rates different from each other. In addition, the controller may be configured to control the first gas supply unit and the second gas supply unit such that a ratio of a process gas to an inert gas of the first gas and a ratio of a process gas to an inert gas of the second gas are different from each other. At this time, the controller may be configured to control the first gas supply unit and the second gas supply unit such that the ratio of the process gas to the inert gas of the second gas is higher than the ratio of the process gas to the inert gas of the first gas.

According to another aspect of the present disclosure, the first gas may further include a gas that is not included in the second gas.

According to another aspect of the present disclosure, the connection part may include a connection housing in which a shutter lift opening is formed such that the shutter is capable of being moved to the substrate entrance passage, and the substrate entrance passage and the processing space may be in communication with each other through the shutter lift opening.

According to another aspect of the present disclosure, the controller may be configured to control the second gas supply unit such that the second gas is intermittently supplied to the substrate entrance passage while the first gas is supplied to the processing space.

According to still another aspect of the present disclosure, there is provided a substrate processing apparatus including: an index module including a load port on which a carrier where a substrate is stored is seated, the index module including a transfer frame including an index robot for transferring the substrate from the carrier seated on the load port; a load lock chamber connected to the index module, the load lock chamber including a buffer stage where the substrate transferred from the index robot waits; a transfer chamber connected to the load lock chamber, the transfer chamber including a transfer robot configured to transfer the substrate from between the load lock chamber and a process chamber; the process chamber connected to the transfer chamber, the process chamber having an inner portion provided with a processing chamber in which a substrate processing process is performed; a connection part connecting the process chamber and the transfer chamber to each other and having an inner portion provided with a substrate entrance passage; a first gas supply unit configured to supply a first gas to the processing space; a second gas supply unit configured to supply a second gas to the substrate entrance passage; and a controller configured to control the first gas supply unit and the second gas supply unit.

According to still another aspect of the present disclosure, the process chamber may further include: a substrate support unit for supporting the substrate; a shower head unit for supplying a gas supplied from the first gas supply unit to the processing space; and a plasma generation unit for generating plasma in the processing space, wherein the controller may be configured to control the plasma generation unit so as to generate plasma in the processing space and to process the substrate while the first gas is supplied to the processing space and the second gas is supplied to the substrate entrance passage.

According to the present disclosure, since the pressure in the corresponding space is adjusted by supplying a gas to the substrate entrance passage, there is an effect that the gas flow disturbance within the process chamber caused by the substrate entrance passage is capable of being solved.

In addition, according to the present disclosure, there is an effect that a process condition for a region of the substrate toward the substrate entrance passage is capable of being finely adjusted by adjusting the type, the composition ratio, the flow rate, and so on of the gas supplied to the substrate entrance passage.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a configuration diagram schematically illustrating a substrate processing apparatus according to an embodiment of the present disclosure;

FIG. 2 is a view illustrating a configuration of a process chamber and a configuration of a connection part according to an embodiment of the present disclosure;

FIG. 3 is a view illustrating a shutter driving unit according to an embodiment of the present disclosure;

FIG. 4 is a flowchart illustrating a substrate processing method according to an embodiment of the present disclosure;

FIG. 5A and FIG. 5B are views for describing effects according to an embodiment of the present disclosure; and

FIG. 6 and FIG. 7 are views illustrating the substrate processing apparatus according to another embodiment of the present disclosure.

### DETAILED DESCRIPTION OF THE INVENTION

Hereinbelow, an embodiment of the present disclosure will be described in detail with reference to the accompanying drawings such that the present disclosure can be easily embodied by one of ordinary skill in the art to which the present disclosure belongs. However, the present disclosure is not limited to the embodiment described herein and may be embodied in many different forms.

In order to clearly describe the present disclosure, parts irrelevant to the description are omitted, and the same reference numerals designate the same or similar components throughout the specification.

In addition, in various exemplary embodiments, components having the same configuration will be described only in representative exemplary embodiments by using the same reference numerals, and in other exemplary embodiments, only configurations different from the representative exemplary embodiments will be described.

Throughout the present specification, when a part is referred to as “including” an element, it means that the part may include other elements as well without excluding the other elements unless specifically stated otherwise.

Unless defined otherwise, all terms used herein including technical or scientific terms have the same meanings as generally understood by a person having ordinary knowledge in the art to which the present disclosure pertains. The terms defined in general dictionaries are construed as having meanings consistent with the contextual meanings of the art, but not interpreted as ideal meanings or excessively formal meanings unless explicitly defined in the present application.

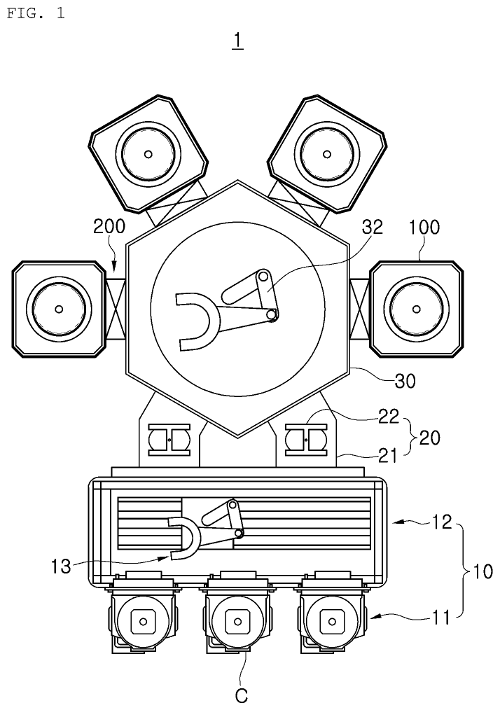

FIG. 1 is a configuration diagram schematically illustrating a substrate processing apparatus according to an embodiment of the present disclosure.

Referring to FIG. 1, a substrate processing apparatus 1 according to an embodiment of the present disclosure includes an index module 10, a load lock chamber 20, a transfer chamber 30, and a process chamber 100.

The index module 10 may be an Equipment Front End Module (EFEM), and may include a load port 11 and a transfer frame 12.

The load port 11 is provided with a carrier C in which a non-processed substrate or a processed substrate is stored. The carrier C may be a Front Opening Unified Pod (FOUP). A plurality of load ports 11 may be mounted on the index module 10.

The transfer frame 12 includes an index robot 13 configured to carry a substrate from between the load lock chamber 20 and the carrier C that is seated on the load port 11. The transfer frame 12 may be maintained in an atmospheric pressure atmosphere.

The load lock chamber 20 is disposed between the index module 10 and the transfer chamber 30 and performs a buffer function. The load lock chamber 20 may be provided with a buffer stage 22 inside a housing 21. The buffer stage 22 may provide a space in which the substrate temporarily waits until the unprocessed substrate is loaded into the load lock chamber 20 and then is delivered to the transfer robot 32 of the transfer chamber 30, or may provide a space in which the substrate temporarily waits until the processed substrate is delivered to the load lock chamber 20 by the transfer robot 32 and then is delivered to the index robot 13. The load lock chamber 20 may be switched between a depressurized atmosphere and an atmospheric pressure atmosphere. In order to deliver the substrate from between the load lock chamber 20 and the index robot 13, the atmosphere of the load lock chamber 20 may be switched to the atmospheric pressure atmosphere. Furthermore, in order to deliver the substrate from between the load lock chamber 20 and the transfer robot 32, the atmosphere of the load lock chamber 20 substrate may be switched to the depressurized atmosphere.

The atmosphere of the transfer chamber 30 is maintained in the depressurized atmosphere, and the substrate is carried from between the load lock chamber 20 and the process chamber 100 by using the transfer robot 32. The transfer robot 32 may be configured to perform a lifting movement, a rotation movement, and a forward-backward movement. Furthermore, the transfer robot 32 may perform a function of returning the unprocessed substrate from the load lock chamber 20 to the process chamber 100 or returning the processed substrate from the process chamber 100 to the load lock chamber 20.

The transfer chamber 30 may be formed in a polygonal shape including a plurality of sides. For example, the transfer chamber 30 may be formed in a hexagonal or may be formed in a rectangular shape, but is not limited thereto. Each side of the transfer chamber 30 is connected to the process chamber 100 or the load lock chamber 20. In FIG. 1, an example in which the transfer chamber 30 is formed in the hexagonal shape, each process chamber 100 is connected to four sides of the hexagonal shape, and the remaining two sides of the hexagonal shape are connected to each load lock chamber 20 is illustrated.

The process chamber 100 provides a processing space S in which a predetermined process such as an etching process, a deposition process, and so on are performed on the substrate, and the process chamber 100 is connected to the transfer chamber 30 by a connection part 200.

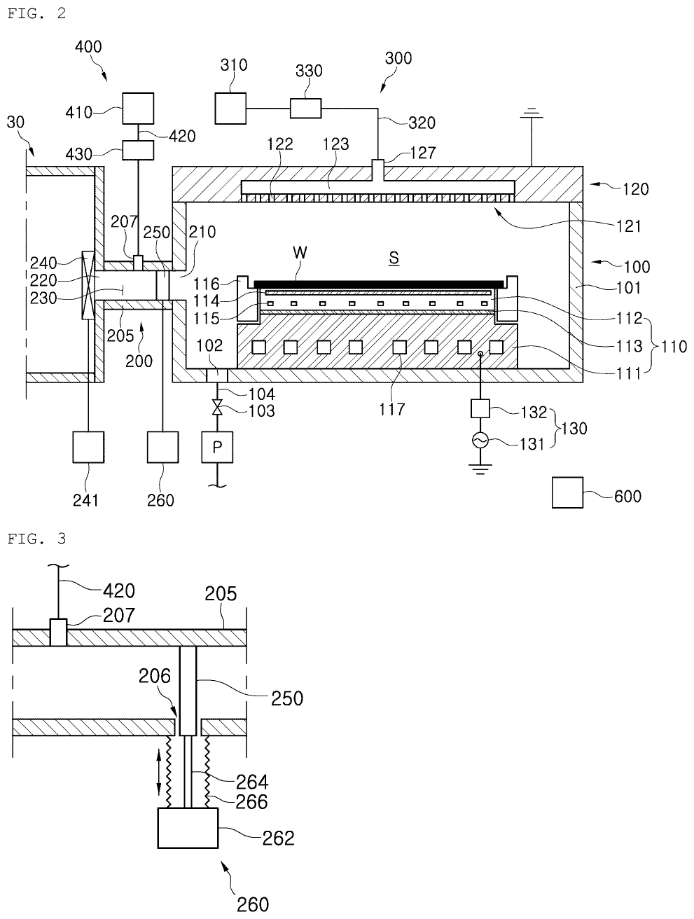

FIG. 2 is a view illustrating a configuration of the process chamber 100 and the connection part 200 according to an embodiment of the present disclosure.

Referring to FIG. 2, the process chamber 100 provides the processing space S inside a chamber body 101 in which a substrate processing process is performed. The chamber body 101 may be formed of metal such as aluminum and so on. The substrate processing process may be a process of plasma processing a substrate W. For example, the substrate processing process may be a plasma etching process. The substrate processing process may be performed in a depressurized atmosphere. To this end, an exhaust port 102 may be formed in the process chamber 100. The exhaust port 102 may be formed on the bottom of the process chamber 100. An exhaust pump P is connected to the exhaust port 102 by an exhaust line 104 and an exhaust valve 103. By operating the exhaust pump P and adjusting the exhaust valve 103, a pressure in the processing space S inside the process chamber 100 may be adjusted to a predetermined pressure.

A substrate support unit 110 for supporting the substrate W is provided inside the process chamber 100. The substrate support unit 110 may include a base plate 111, and may include an electrostatic chuck 112 which is supported on the base plate 111 and which is configured to fix the substrate W by adsorbing the substrate W. The base plate 111 and the electrostatic chuck 112 may be bonded to each other by a bonding layer 113, and the bonding layer 113 may be formed of a silicone adhesive and so on.

The electrostatic chuck 112 may be formed of a dielectric plate such as alumina, and an inner portion of the electrostatic chuck 112 may be provided with a chucking electrode 114 for generating an electrostatic force on the inner portion of the electrostatic chuck 112. When a voltage is applied to the chucking electrode 114 by a power source that is not illustrated, the electrostatic force is generated, and the substrate W is adsorbed and fixed to the electrostatic chuck 112. The electrostatic chuck 112 may be provided with a heater 115 for adjusting the temperature of the substrate W. The heater 115 may be formed of a plurality of zone heaters separated from each other so as to independently control the temperature of each region of the substrate W.

The base plate 111 is positioned below the electrostatic chuck 112, and may be formed of a metal material such as aluminum. In the base plate 111, a refrigerant flow path 117 in which a cooling fluid flows is formed inside the base plate 111, so that the base plate 111 may serve as a cooling mechanism for cooling the substrate W. The refrigerant flow path 117 may be provided as a circulation passage through which the cooling fluid is circulated.

The substrate support unit 110 may include a ring member 116 surrounding the electrostatic chuck 112. A step may be formed on the upper portion of the ring member 116 such that the ring member 116 supports the outer circumferential surface of the substrate W. The ring member 116 may be formed of a ceramic material, and may be a focus ring.

A shower head unit 120 may be provided on the upper portion of the process chamber 100. The shower head unit 120 may include a shower plate 121 having a plurality of gas supply holes 122, a gas distribution chamber 123, and a first gas inlet 127. A gas supplied from a first gas supply unit 300 may be introduced into the gas distribution chamber 123 through the first gas inlet 127, and then may be supplied to the processing space S through the gas supply holes 122.

The first gas supply unit 300 is configured to supply the gas required for processing the substrate W to the processing space S. The first gas supply unit 300 may include a first gas supply source 310, a first gas supply line 320, and a first gas flow rate controller 330. The first gas supply line 320 may connect the first gas supply source 310 and the first gas inlet 127 to each other, and the first gas flow rate controller 330 may adjust the flow rate of gas flowing through the first gas supply line 320 or may block the first gas supply line 320.

In FIG. 2, only one first gas supply source 310, the first gas supply line 320, and the first gas flow rate controller 330 are respectively illustrated. However, in order to supply a plurality of gases to the processing space S, the first gas supply unit 300 of the present disclosure may include a plurality of gas supply sources and a plurality of gas flow rate controllers capable of independently controlling the supply of each of the gases. The plurality of gases may include a process gas used in the processing process of the substrate W. For example, the plurality of gases may include an etching gas, an inert gas for purging, and so on.

A plasma generation unit 130 may include a high frequency power source 131 for generating plasma in the processing space S by supplying high frequency electric power, and may include a matching device 132 for impedance matching. The high frequency power source 131 may provide high frequency electric power in the range of several hundred kHz to several hundred MHz.

The high frequency power source 131 may supply high frequency electric power to the substrate support unit 110 that functions as a lower electrode. At this time, the shower head unit 120 that functions as an upper electrode is capable of being grounded. Since it is illustrated in FIG. 2 that the high frequency power source 131 is connected to the lower electrode, but this should be understood as an example. In order to generate plasma in the processing space S, high frequency electric power may be applied to the upper electrode, and the lower electrode may be grounded. In addition, optionally, high frequency power may be applied to both the upper electrode and the lower electrode. As the high frequency power source 131, a plurality of high frequency power sources having different frequencies may be used.

The high frequency power source 131 may continuously apply electric power or may apply power in a pulse mode.

A first opening 210 as an entrance for the substrate W to enter and exit therethrough may be formed on a side wall of the process chamber 100. The first opening 210 is connected to the transfer chamber 30 by the connection part 200. A second opening 220 is formed on a side wall of the transfer chamber 30 that is connected to the connection part 200. That is, the substrate W may be carried into the processing space S through the second opening 220 of the transfer chamber 30, the connection part 200, and the first opening 210 of the process chamber 100.

The connection part 200 is a portion connecting the process chamber 100 and the transfer chamber 30 to each other. Specifically, the connection part 200 connects the first opening 210 of the process chamber 100 and the second opening 220 of the transfer chamber 30 to each other, thereby providing a passage through which the substrate W is moved. The connection part 200 includes a connection housing 205 that is connected to the process chamber 100 and the transfer chamber 30. The internal space of the connection housing 205 provides a substrate entrance passage 230, and is in communication with the internal space of the transfer chamber 30 and the processing space S.

An opening and closing door 240 is configured to open and close the second opening 220. The opening and closing door 240 may be provided inside the transfer chamber 30 such that the opening and closing door 240 is capable of being moved between an opening position where the second opening 220 is opened and a closing position where the second opening 220 is closed. The opening and closing door 240 may be moved between the opening position and the closing position by an opening and closing door driving unit 241. When the opening and closing door 240 is positioned in the closing position, a state in which the opening and closing door 240 and the side wall of the transfer chamber 30 are airtightly sealed may be realized. The opening and closing door 240 may be a gate valve.

A shutter 250 is provided such that the shutter 250 is capable of blocking the first opening 210. By a shutter driving unit 260, the shutter 250 may be moved between an opening position where the first opening 210 is opened and a blocking position where the first opening 210 is blocked. When the substrate W is carried into the processing space S and is supported on the substrate support unit 110 and then the substrate processing process is performed, the shutter 250 may be moved to the blocking position, so that the first opening 210 and the substrate entrance passage 230 may be blocked from the processing space S. As a result, disturbance of the gas flow due to the first opening 210 or heat loss from the substrate support unit 110 may be suppressed.

In FIG. 2, it is illustrated that the shutter 250 is disposed in the side of the connection housing 205 such that the shutter 250 is capable of blocking the first opening 210, but the position of the shutter 250 is not limited thereto. The shutter 250 may be disposed in the side of the processing space S of the process chamber 100 such that the shutter 250 is capable of blocking the first opening 210, and may be configured such that the shutter 250 is mounted in the side wall of the process chamber 100 and is moved between the opening position and the blocking position.

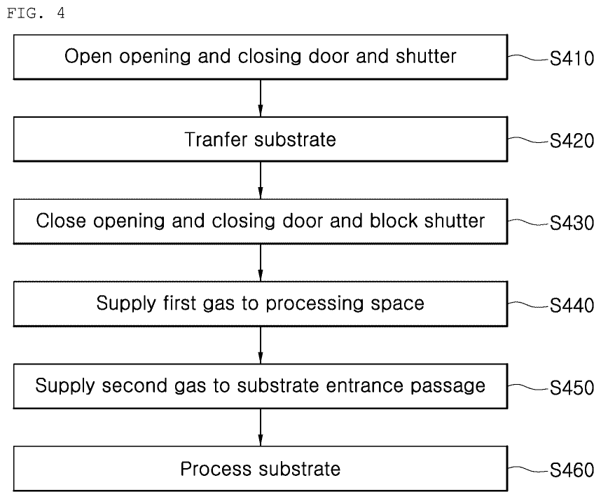

FIG. 3 is a view illustrating the shutter driving unit 260 according to an embodiment of the present disclosure.

The shutter driving unit 260 according to an embodiment of the present disclosure may include a power source 262, a lifting rod 264, and a bellows 266. The power source 262 is capable of lifting up and down the shutter 250 by generating a driving force that lifts up or down the lifting rod 264, the shutter 250 being connected to the lifting rod 264. The shutter 250 may be lifted up and down through a shutter lift opening 206 formed in the connection housing 205. At this time, the bellows 266 may be provided so that the shutter 250 is capable of being lifted up and down while the substrate entrance passage 230 is blocked from external air. The bellows 266 may be disposed between the connection housing 205 and the power source 262.

Referring to FIG. 2 and FIG. 3, a second gas inlet 207 for supplying a second gas to the substrate entrance passage 230 may be formed in the connection housing 205, and the second gas inlet 207 may be connected to a second gas supply unit 400. The second gas supply unit 400 may include a second gas supply source 410, a second gas supply line 420, and a second gas flow rate controller 430. In a state in which the opening and closing door 240 closes the second opening 220 and the shutter 250 blocks the first opening 210, the second gas supply unit 400 may supply the second gas to the substrate entrance passage 230.

The controller 600 may control the overall operation of the substrate processing apparatus 1. As an example, the controller 600 may dispose the substrate W on the substrate support unit 110 by controlling operations of the transfer robot 32, the opening and closing door 240, the shutter 250, a lifting pin (not illustrated) provided on the substrate support unit 110, and so on.

In addition, the controller 600 may be configured such that the plasma processing process is performed on the substrate W by controlling operations of the first gas supply unit 300 and the plasma generation unit 130. For example, the controller 600 may control the first gas supply unit 300 such that a predetermined etching gas is supplied to the processing space S, may control the second gas supply unit 400 such that the second gas is supplied to the substrate entrance passage 230, and may control the high frequency power source 131 such that plasma is generated in the processing space S, thereby etching the substrate W.

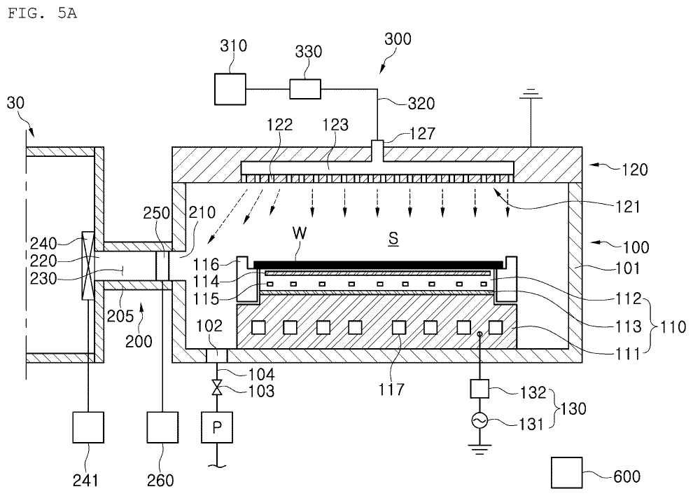

FIG. 4 is a flowchart illustrating a substrate processing method according to an embodiment of the present disclosure. A substrate processing method according to an embodiment of the present disclosure may be performed by a control of the controller 600.

Referring to FIG. 4, the substrate processing method according to an embodiment of the present disclosure may include a process of opening an opening and closing door and a shutter S410, a substrate carrying process S420, a process of closing the opening and closing door and blocking the shutter S430, a first gas supply process S440, a second gas supply process S450, and a substrate processing process S460.

the process of opening the opening and closing door and the shutter S410 is a process in which the controller 600 controls the opening and closing door driving unit 241 such that the opening and closing door 240 is moved to the opening position and the controller 600 controls the power source 262 such that the shutter 250 is moved to the opening position. In a state in which the shutter 250 is already positioned in the opening position, a process of moving the opening and closing door 240 to the opening position may only be performed. By performing the process of opening the opening and closing door and the shutter S410, the first opening 210 of the process chamber 100 and the second opening 220 of the transfer chamber 30 are opened, and a state in which the transfer chamber 30 and the process chamber 100 are in communication with each other by the substrate entrance passage 230 of the connection part is realized.

The substrate carrying process S420 is a process in which the controller 600 controls the transfer robot 32 such that the substrate W is carried into the process chamber 100. The substrate W may be carried into the processing space S while being in a state in which the substrate W is supported by the transfer robot 32, and the substrate W may be seated on the substrate support unit 110. In order to transfer the substrate W from the transfer robot 32 to the substrate support unit 110, the controller 600 may control lifting of the lifting pin (not illustrated) provided in the substrate support unit 110. When the substrate W is seated on the substrate support unit 110, the controller 600 may perform a control such that a voltage is applied to the chucking electrode 114 so that the substrate W is adsorbed to the electrostatic chuck 112. The transfer robot 32 is controlled such that the transfer robot 32 is return to the transfer chamber 30 when the substrate W is transferred to the substrate support unit 110.

the process of closing the opening and closing door and blocking the shutter S430 is a process in which the controller 600 controls the opening and closing door driving unit 241 such that the opening and closing door 240 is moved to the closing position and the controller 600 controls the power source 262 such that the shutter 250 is moved to the blocking position. In this process S430, the processing space S may be isolated from the transfer chamber 30 by the opening and closing door 240, and may be blocked from the substrate entrance passage 230 by the shutter 250. At this time, while the opening and closing door 240 is in a state in which the opening and closing door is airtightly sealed with the side wall of the transfer chamber 30, the processing space S and the substrate entrance passage 230 are not completely isolated from each other by the shutter 250. This is because, even if the shutter 250 is lifted up until the shutter 250 is in contact with the inner surface of the connection housing 205, the contact surface is not in an airtight sealing state in which a gas cannot pass through the contact surface and, in addition, the substrate entrance passage 230 and the processing space S are in communication with each other through the shutter lift opening 206 formed in the connection housing 205 so as to realize lifting of the shutter 250.

The first gas supply process S440 is a process in which a first gas is supplied to the processing space S in order to perform a predetermined process on the substrate W. The controller 600 may control the first gas supply unit 300 such that the first gas is supplied to the processing space S through the shower head unit 120. The first gas is a gas used in the substrate processing process, and may include a process gas such as an etching gas, for example. The first gas does not refer to a single gas, but refers to the entire gas supplied to the processing space S for the substrate processing process. The first gas may be a mixture of a process gas and an inert gas. The process gas contained in the first gas may include at least one of a fluorine-containing gas, a hydrogen-containing gas, a phosphorus-containing gas, a halogen-containing gas, a carbon-containing gas, a nitrogen-containing gas, an oxygen-containing gas, and a sulfur-containing gas.

By the flow of the first gas supplied to the processing space S, the pressure in the processing space S may be adjusted to a first pressure P1 for the substrate processing process. That is, by the first gas flow rate controller 330 controlled by the controller 600, the first gas is supplied at a predetermined flow rate to the shower head unit 120 and is discharged through the exhaust port 102. By this gas flow, the atmosphere of the processing space S is adjusted to a first gas atmosphere at the first pressure P1.

Meanwhile, since the substrate entrance passage 230 is blocked from the processing space S by the shutter 250 before the first gas supply process S440, the gas atmosphere and the pressure of the substrate entrance passage 230 may be different from the gas atmosphere and the pressure of the processing space S even if the first gas is supplied to the processing space S. That is, although the substrate entrance passage 230 is not completely isolated from the processing space S, due to the blocking effect by the shutter 250, it is not easy for the first gas supplied to the processing space S to be introduced into the substrate entrance passage 230. Therefore, the pressure of the substrate entrance passage 230 may be a second pressure P2 different from the first pressure P1.

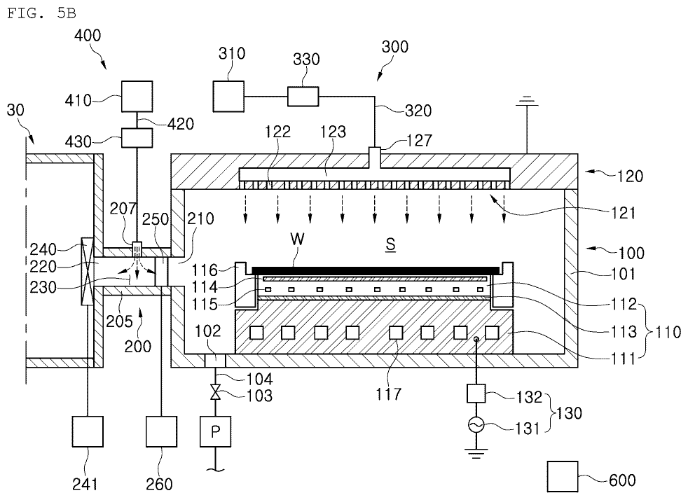

Generally, by the supply of the first gas, the pressure of the processing space S is increased until the pressure of the processing space S reach a process pressure, so that the second pressure P2 may be lower than the first pressure P1. Due to such a pressure difference, the first gas supplied to the processing space S may exhibit a different flow behavior in a region adjacent to the first opening 210 than the remaining region of the processing space S. That is, as illustrated in FIG. 5A, an effect in which the first gas supplied from the shower head unit 120 is induced toward the first opening 210 having a relatively low pressure may occur in a position adjacent to the first opening 210, which may affect the processing process for a region of the substrate in a direction of the first opening 210.

In the present disclosure, in order to solve this problem, the second gas supply process S450 in which the second gas is supplied to the substrate entrance passage 230 may be performed. The controller 600 may control the second gas supply unit 400 such that the second gas is supplied to the substrate entrance passage 230. The second gas supply process S450 may be performed simultaneously with the first gas supply process S440, and may be performed continuously or intermittently while the second gas supply process S440 is performed simultaneously with the first gas supply process S440. The first gas supply process S440 and the second gas supply process S450 may be performed such that the first gas supply process S440 and the second gas supply process S450 overlap at least some time intervals.

The pressure of the substrate entrance passage 230 may be increased by the supply of the second gas, so that the phenomenon in which the first gas supplied to the processing space S is induced toward the first opening 210 at the position adjacent to the first opening 210 may be suppressed. That is, as illustrated in FIG. 5B, a first gas flow substantially the same as another direction may be formed even at the position adjacent to the first opening 210, so that a uniform substrate processing independent of the direction may be realized.

The second gas supplied to the substrate entrance passage 230 may be an inert gas. By using an inert gas, the influence on the substrate processing process by the second gas supply may be minimized.

The second gas supplied to the substrate entrance passage 230 may be moved to the processing space S through the shutter lift opening 206, and then may be discharged to the exhaust port 102 by being swept by the first gas flow.

It is illustrated in FIG. 4 that the first gas supply process S440 is performed before the second gas supply process S450, but the present disclosure is not limited thereto. For example, the second gas supply process S450 may be started first, and the first gas supply process S440 may be started while the second gas is supplied to the substrate entrance passage 230. In addition, the second gas supply process S450 may be stopped after the first gas supply process S440 is completed. By allowing the second gas to be continuously supplied to the substrate entrance passage 230 while the first gas is supplied, contamination of the substrate entrance passage by the first gas may be suppressed.

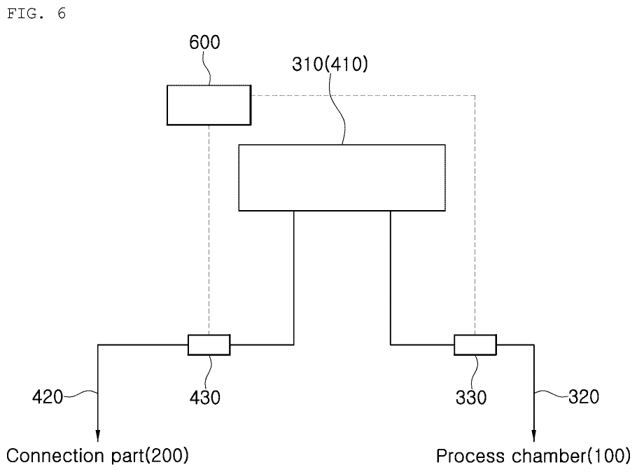

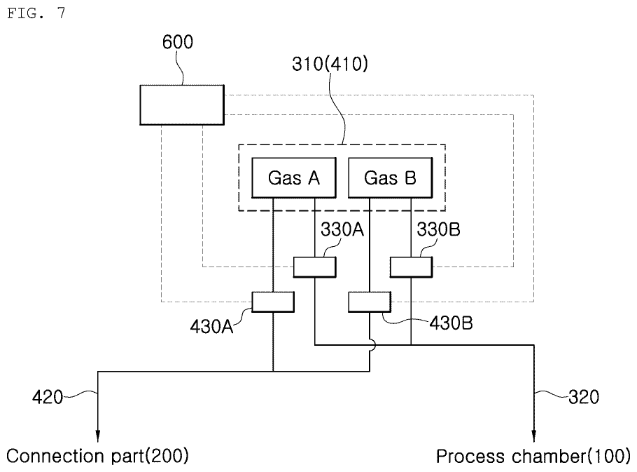

FIG. 6 and FIG. 7 are views illustrating the substrate processing apparatus and the substrate processing method according to another embodiment of the present disclosure.

An embodiment in FIG. 6 is an example in which the same gas is used as the first gas and the second gas. That is, the first gas supply source 310 and the second gas supply source 410 use a common gas supply source. The first gas is supplied to the process chamber 100 through the first gas supply line 320 and, at this time, the controller 600 controls the first gas flow rate controller 330 such that the flow rate of the first gas supplied to the process chamber 100 is adjusted. The second gas is supplied to the connection part 200 through the second gas supply line 420 and, at this time, the controller 600 controls the second gas flow rate controller 430 such that the flow rate of the second gas supplied to the connection part 200 is adjusted. Since the first gas and the second gas are the same, the same gas with different flow rates only may be supplied to the processing space S of the process chamber 100 and to the substrate entrance passage 230 of the connection part 200. Therefore, even when the second gas supplied to the substrate entrance passage 230 is moved to the processing space S through the shutter lift opening 206 and the second gas is mixed with the first gas, the first gas composition of the processing space S may not be affected. The flow rate of the second gas may be adjusted to a predetermined flow rate so that a uniform process processing is capable of being realized over the entire surface of the substrate.

An embodiment of FIG. 7 is an example in which the composition of the first gas and the composition of the second gas are capable of being adjusted. Referring to FIG. 7, the first gas supply source 310 and the second gas supply source 410 are configured to supply a plurality of gases. For example, the first gas supply source 310 and the second gas supply source 410 are configured to supply a gas A and a gas B. The gas A may be a process gas such as an etching gas, and the gas B may be an inert gas. It is illustrated in FIG. 7 that the first gas supply source 310 and the second gas supply source 410 use a common gas supply source, but there is no limitation. Separate gas supply sources respectively configured to supply the gas A and the gas B may be used.

The first gas supply source 310 is configured to supply the gas A to the processing space S of the process chamber 100 through a first gas A flow rate controller 330A, and is configured to supply the gas B to the processing space S of the process chamber 100 through a first gas B flow rate controller 330B. The controller may adjust the composition of the gas supplied to the processing space S by controlling the first gas A flow rate controller 330A and the first gas B flow rate controller 330B.

The second gas supply source 410 is configured to supply the gas A to the substrate entrance passage 230 of the connection part 200 through a second gas A flow rate controller 430A, and is configured to supply the gas B to the substrate entrance passage 230 of the connection part 200 through a second gas B flow rate controller 430B. The controller may adjust the composition of the gas supplied to the substrate entrance passage 230 by controlling the second gas A flow rate controller 430A and the second gas B flow rate controller 430B.

According to this configuration, the composition of the gas supplied to the processing space S and the composition of the gas supplied to the substrate entrance passage 230 may be adjusted to be different from each other. For example, when a process processing result of the substrate region in the direction of the first opening 210 is different from the remaining region of the substrate even though the second gas is supplied to the substrate entrance passage 230 so that the pressure in the substrate entrance passage 230 and the pressure in the processing space S are substantially the same, the difference in the process processing result may be compensated by adjusting the composition of the second gas.

In the plasma etching process as an example, the etching rate of the substrate region in the direction of the first opening 210 may be smaller than that of the remaining region due to various complex factors such as plasma density, substrate temperature, and so on. In order to compensate for this, the composition of the second gas may be adjusted such that the ratio of the process gas in the second gas is higher than the ratio of the process gas in the first gas. That is, the component ratio of the process gas to the inert gas may be adjusted such that the component ratio of the process gas to the inert gas is higher in the second gas than in the first gas. Since the second gas having a relatively high ratio of the process gas is moved to the processing space S through the shutter lift opening 206 and is mixed with the first gas, the composition of the first gas adjacent to the first opening 210 of the processing space S may be locally different from the remaining region. The component or the flow rate of the second gas may be adjusted to a predetermined flow rate so that a uniform process processing is capable of being realized over the entire surface of the substrate.

It is illustrated in FIG. 7 that the first gas and the second gas include the same gas (the gas A and the gas B), but it should be understood that the present disclosure is not limited thereto. For example, the first gas may include a gas that is not included in the second gas. Conversely, the second gas may include a gas that is not included in the first gas.

The present exemplary embodiment and the accompanying drawings in this specification only clearly show a part of the technical idea included in the present disclosure, and it will be apparent that all modifications and specific exemplary embodiments that can be easily inferred by those skilled in the art within the scope of the technical spirit contained in the specification and drawings of the present disclosure are included in the scope of the present disclosure.

Therefore, the spirit of the present disclosure should not be limited to the described exemplary embodiments, and all things equal or equivalent to the claims as well as the claims to be described later fall within the scope of the concept of the present disclosure.

What is claimed is:

1. A substrate processing apparatus comprising:
a process chamber providing a processing space for performing substrate processing;
a transfer chamber comprising a transfer robot for transferring a substrate to the process chamber, the transfer chamber being connected to the process chamber by a connection part;
a first gas supply unit configured to supply a first gas to the processing space;
a second gas supply unit configured to supply a second gas to a substrate entrance passage that is a space inside the connection part;
and a controller configured to control the first gas supply unit and the second gas supply unit.

2. The substrate processing apparatus of claim 1, wherein a first opening for allowing the substrate to enter and exit therethrough is formed on a side wall of the process chamber, a second opening for allowing the substrate to enter and exit therethrough is formed on a side wall of the transfer chamber, and the first opening and the second opening are in communication with each other by the substrate entrance passage.

3. The substrate processing apparatus of claim 2, further comprising:
an opening and closing door configured to be moved between an opening position for opening the second opening and a closing position for closing the second opening; and
a shutter configured to be moved between an opening position for opening the first opening and a blocking position for blocking the first opening.

4. The substrate processing apparatus of claim 3, wherein the first gas supply unit comprises a first gas supply source and a first gas flow rate controller, and the first gas supply unit is configured to supply the first gas to the processing space through a first gas inlet that is provided in the process chamber,
the second gas supply unit comprises a second gas supply source and a second gas flow rate controller, and the second gas supply unit is configured to supply the second gas to the substrate entrance passage through a second gas inlet formed in a connection housing of the connection part, and
the controller is configured to control the first gas flow rate controller and the second gas flow rate controller so that periods during which the first gas and the second gas are supplied overlap at least partially.

5. The substrate processing apparatus of claim 4, wherein a shutter lift opening is formed in the connection housing such that the shutter is capable of being moved to the substrate entrance passage.

6. The substrate processing apparatus of claim 5, wherein the controller is configured to control the second gas supply unit such that the second gas is supplied to the substrate entrance passage when the opening and closing door is positioned in the closing position and the shutter is positioned in the blocking position.

7. The substrate processing apparatus of claim 4, wherein the first gas supply source and the second gas supply source are the same common gas supply source.

8. A substrate processing apparatus comprising:
a process chamber providing a processing space for performing substrate processing, the process chamber having a side wall provided with a first opening for allowing a substrate to enter and exit therethrough;
a transfer chamber comprising a transfer robot for transferring the substrate to the process chamber, the transfer chamber having a side wall provided with a second opening for allowing the substrate to enter and exit therethrough;
a connection part connecting the first opening of the process chamber and the second opening of the transfer chamber to each other, the connection part having an inner portion provided with a substrate entrance passage;
a first gas supply unit configured to supply a first gas to the processing space;
a second gas supply unit configured to supply a second gas to the substrate entrance passage; and
a controller,
wherein the controller is configured to:
control the first gas supply unit such that the first gas is supplied to the processing space after the substrate is transferred to the processing space; and
control the second gas supply unit such that the second gas is supplied to the substrate entrance passage while the first gas is supplied to the processing space.

9. The substrate processing apparatus of claim 8. further comprising:
an opening and closing door configured to be operated by an opening and closing door driving unit such that the opening and closing door is moved between an opening position for opening the second opening and a closing position for closing the second opening; and
a shutter configured to be operated by a power source such that the shutter is moved between an opening position for opening the first opening and a blocking position for blocking the first opening,
wherein the controller is configured to control the opening and closing door driving unit, the power source, and the second gas supply unit such that the second gas is supplied to the substrate entrance passage in a state in which the opening and closing door is positioned in the closing position and the shutter is positioned in the blocking position.

10. The substrate processing apparatus of claim 9, wherein the first gas comprises a process gas and an inert gas, and the second gas comprises an inert gas.

11. The substrate processing apparatus of claim 9, wherein each of the first gas and the second gas comprises a process gas and an inert gas.

12. The substrate processing apparatus of claim 11, wherein the controller is configured to control the first gas supply unit and the second gas supply unit such that the first gas and the second gas are supplied at flow rates different from each other.

13. The substrate processing apparatus of claim 11, wherein the controller is configured to control the first gas supply unit and the second gas supply unit such that a ratio of the process gas to the inert gas of the first gas and a ratio of the process gas to the inert gas of the second gas are different from each other.

14. The substrate processing apparatus of claim 13, wherein the controller is configured to control the first gas supply unit and the second gas supply unit such that the ratio of the process gas to the inert gas of the second gas is higher than the ratio of the process gas to the inert gas of the first gas.

15. The substrate processing apparatus of claim 8, wherein the first gas further comprises a gas that is not included in the second gas.

16. The substrate processing apparatus of claim 8, wherein the connection part comprises a connection housing in which a shutter lift opening is formed such that a shutter is capable of being moved to the substrate entrance passage, and the substrate entrance passage and the processing space are in communication with each other through the shutter lift opening.

17. The substrate processing apparatus of claim 8, wherein the controller is configured to control the second gas supply unit such that the second gas is intermittently supplied to the substrate entrance passage while the first gas is supplied to the processing space.

18. A substrate processing apparatus comprising:
an index module comprising a load port on which a carrier where a substrate is stored is seated, the index module comprising a transfer frame comprising an index robot for transferring the substrate from the carrier seated on the load port;
a load lock chamber connected to the index module, the load lock chamber comprising a buffer stage where the substrate transferred from the index robot waits;
a transfer chamber connected to the load lock chamber, the transfer chamber comprising a transfer robot configured to transfer the substrate from between the load lock chamber and a process chamber, wherein the process chamber is connected to the transfer chamber, the process chamber has an inner portion provided with a processing space in which a substrate processing process is performed;
a connection part connecting the process chamber and the transfer chamber to each other and having an inner portion provided with a substrate entrance passage;
a first gas supply unit configured to supply a first gas to the processing space;
a second gas supply unit configured to supply a second gas to the substrate entrance passage; and
a controller configured to control the first gas supply unit and the second gas supply unit.

19. The substrate processing apparatus of claim 18, further comprising:
an opening and closing door configured to be operated by an opening and closing door driving unit such that the opening and closing door is moved between an opening position for opening a second opening and a closing position for closing the second opening, the second opening being formed on a side wall of the transfer chamber so as to allow the substrate to enter and exit therethrough; and
a shutter configured to be operated by a power source such that the shutter is moved between an opening position for opening a first opening and a blocking position for blocking the first opening, the first opening being formed on a side wall of the process chamber so as to allow the substrate to enter and exit therethrough,
wherein the controller is configured to control the opening and closing door driving unit, the power source, and the second gas supply unit such that the second gas is supplied to the substrate entrance passage in a state in which the opening and closing door is positioned in the closing position and the shutter is positioned in the blocking position.

20. The substrate processing apparatus of claim 19, wherein the process chamber further comprises:
a substrate support unit for supporting the substrate;
a shower head unit for supplying the first gas supplied from the first gas supply unit to the processing space; and
a plasma generation unit for generating plasma in the processing space, and
wherein the controller is configured to control the plasma generation unit so as to generate the plasma in the processing space and to process the substrate while the first gas is supplied to the processing space and the second gas is supplied to the substrate entrance passage.
